(19) United States
(12) Patent Application Publication
(10) Pub. No.: US 2011/0117746 A1
(43) Pub. Date: May 19, 2011

(54) COATING COMPOSITION AND PATTERN FORMING METHOD

(75) Inventors: Daisuke Maruyama, Toyama-shi (JP); Yasushi Sakaida, Toyama-shi (JP); BangChing Ho, Toyama-shi (JP); Keisuke Hashimoto, Toyama-shi (JP); Noriaki Fujitani, Toyama-shi (JP)

(73) Assignee: NISSAN CHEMICAL INDUSTRIES, LTD., TOKYO (JP)

(21) Appl. No.: 13/054,665

(22) PCT Filed: Jul. 23, 2009
(86) PCT No.: PCT/JP2009/063202

§ 371 Date: Jan. 18, 2011

(30) Foreign Application Priority Data
Jul. 24, 2008 (JP) 2008-191206
Jul. 24, 2008 (JP) 2008-191249

(51) Int. Cl. H01L 21/31; C09D 183/04

(52) U.S. Cl. 438/703; 524/257; 257/E21.24

(57) ABSTRACT

It is an object to provide a coating composition applicable to “reversal patterning” and suitable for forming a film covering a resist pattern. The object is accomplished by a coating composition for lithography comprising an organopolysiloxane, a solvent containing the prescribed organic solvent as a main component, and a quaternary ammonium salt or a quaternary phosphonium salt; or a coating composition for lithography comprising a polysilane, a solvent containing the prescribed organic solvent as a main component, and at least one additive selected from a group consisting of a crosslinking agent, a quaternary ammonium salt, a quaternary phosphonium salt, and a sulfonic acid compound, wherein the polysilane has, at a terminal thereof, a silanol group or a silanol group together with a hydrogen atom.

### TECHNICAL FIELD

The present invention relates to a coating composition used in a lithography process in a production process of a semiconductor device and capable of forming a film covering a resist pattern. The present invention relates also to a using method of the coating composition.

### BACKGROUND ART

In recent years, corresponding to the increased degree of integration of semiconductor elements, miniaturization of a pattern such as a wiring is required. In order to form a fine pattern, it is performed to adopt a short-wavelength light such as an ArF excimer laser (wavelength: about 193 nm) as a light source for exposure to form a resist pattern.

The larger the aspect ratio (height/width) of a resist pattern is, the easier the pattern collapse is caused. In order to prevent the pattern collapse, the film thickness of a resist is necessary to be reduced. However, a resist pattern formed from a resist having a small film thickness might disappear, when dry-etching a film to be processed using the resist pattern as a mask.

There is disclosed a patterning method by which it is not necessary to consider the above problem of dry-etching resistance of a resist pattern (for example, see Patent Document 1 to Patent Document 5). In other words, a resist pattern in a shape that is produced by inverting the shape of a desired pattern is formed and a film covering (embedding) the resist pattern is formed by a coating method or the like. Next, the top face of the resist pattern is exposed and the resist pattern is removed. Then, using the thus formed reversal pattern (pattern in a shape that is produced by inverting the shape of a resist pattern) as a mask, a material to be processed is etched. In the present specification, this series of patterning methods is called as “reversal patterning”.

In Patent Documents 1 to 3 and Patent Document 5, a resist pattern and a film covering the resist pattern are formed through an underlayer resist, a film to be processed, or a foundation layer. Then, to the underlayer resist, the film to be processed, or the foundation layer, a pattern in a shape that is produced by inverting the shape of the resist pattern is transferred.

A silicon-containing polymer is a mask material exhibiting high dry-etching resistance to an oxygen gas in comparison with an organic resin film containing no Si atom, so that as the material for the film covering a resist pattern, a silicon-containing polymer can be used. As the silicon-containing polymer, a polysilane is known (for example, see Patent Document 6). Patent Document 6 discloses a polysilane excellent in the solubility in a solvent (toluene, propylene glycol monomethyl ether acetate) and capable of being suitably utilized as a coating liquid (coating agent).

On the other hand, it is known that there is another method for forming a fine pattern. For example, Patent Document 7 and Patent Document 8 disclose a so-called sidewall method. That is, the side wall method is a method including: forming a side wall having a predetermined width on a side face of a photoresist pattern; and removing the photoresist pattern to obtain a fine pattern formed by the side wall. The side wall is formed through a process for forming a silicon-containing polymer layer by coating a photoresist pattern, followed by subjecting the polymer layer and the photoresist pattern to exposure and baking to form a crosslinkage bond layer between the photoresist pattern and the silicon-containing polymer layer, or the like. As the silicon-containing polymer, there are developed a polymer having an epoxy group as a crosslinkable acting group and further, a polymer such as a polysiloxane compound or a polysilsesquioxane-based compound.

### RELATED-ART DOCUMENT

### Patent Document

Patent Document 1: Japanese Patent Application Publication No. JP-A-7-135140
Patent Document 2: Japanese Patent No. 3848070
Patent Document 3: Japanese Patent No. 3697426
Patent Document 4: U.S. Pat. No. 6,569,761
Patent Document 5: US Patent Application Publication No. 2007/0037410 specification
Patent Document 6: Japanese Patent Application Publication No. JP-A-2007-77198
Patent Document 7: Japanese Patent Application Publication No. JP-A-2008-72101
Patent Document 8: Japanese Patent Application Publication No. JP-A-2008-72097

### DISCLOSURE OF THE INVENTION

### Problem to be Solved by the Invention

It is an object of the present invention to provide a coating composition applicable to “reversal patterning” and suitable for forming a film covering a resist pattern. When a film covering a resist pattern is formed by a coating method, it is desired that embedding in the resist pattern and uniformly applying on a substrate are easy, and mixing of the composition with the resist pattern is small. Further, a formed covering film is used as a mask, so that the film has desirably an etching rate smaller than that of a material to be processed. On the contrary, to the covering film, anti-reflection function is not necessary to be imparted.

However, the films for coating a resist pattern disclosed in Patent Document 1 to Patent Document 5 cannot necessarily be mentioned as a film satisfying the above properties. Patent Document 6 cannot be mentioned as disclosing whether a coating liquid using a polysilane is suitable for “reversal patterning” or not, particularly as disclosing the right and wrong of the covering performance of the coating liquid to a resist pattern. Though the silicon-containing polymer layers disclosed in Patent Document 7 and Patent Document 8 may be suitable for forming a crosslinkage bond layer in the above side wall method, the silicon-containing polymer layers are a material that can not necessarily be mentioned as suitable for “reversal patterning”.

### Means for Solving the Problem

A first aspect of the present invention is a coating composition for lithography for forming a film covering a resist pattern, containing an organopolysiloxane, a solvent containing, as a main component, an organic solvent of Formula (1a), Formula (1b), or Formula (1c):

A¹(OA³)ₙOA² (1a)

A⁴OH (1b)

A⁵O(CO)CH₃ (1c)

[where A¹ is a hydrogen atom, a linear, branched, or cyclic C₁₋₆ hydrocarbon group, or an acetyl group; A² is a hydrogen atom, a methyl group, or an acetyl group; A³ is a linear or branched divalent C₂₋₄ hydrocarbon group; A⁴ is a linear, branched, or cyclic C₃₋₆ hydrocarbon group; A⁵ is a linear, branched, or cyclic C₁₋₆ hydrocarbon group; and n is 1 or 2], and

a quaternary ammonium salt or a quaternary phosphonium salt.

A second aspect, of the present invention is a coating composition for lithography for forming a film covering a resist pattern, containing a polysilane, a solvent containing, as a main component, an organic solvent of Formula (1a), Formula (1b), or Formula (1c):

A¹(OA³)ₙOA² (1a)

A⁴OH (1b)

A⁵O(CO)CH₃ (1c)

[where A¹ is a hydrogen atom, a linear, branched, or cyclic C₁₋₆ hydrocarbon group, or an acetyl group; A² is a hydrogen atom, a methyl group, or an acetyl group; A³ is a linear or branched divalent C₂₋₄ hydrocarbon group; A⁴ is a linear, branched, or cyclic C₃₋₆ hydrocarbon group; A⁵ is a linear, branched, or cyclic C₁₋₆ hydrocarbon group; and n is 1 or 2], and

at least one type selected from a group consisting of a crosslinking agent, a quaternary ammonium salt, a quaternary phosphonium salt, and a sulfonic acid compound, in which the polysilane has, at a terminal thereof, a silanol group or a silanol group together with a hydrogen atom.

A third aspect of the present invention is a pattern forming method including: a process for forming a first resist pattern on a semiconductor substrate on which a layer to be processed is formed using an organic resist; a process for applying the coating composition that is the first aspect or the second aspect of the present invention to cover the first resist pattern; a process for forming a covering film by baking the coating composition; a process for exposing an upper part (partially) of the first resist pattern by etching (etching back) the covering film; and a process for removing a part or the whole of the first resist pattern to form a pattern of the covering film. Using the pattern of the covering film as a mask, the layer to be processed is dry-etched. By the pattern forming method, a line, a contact hole, or a trench can be formed.

In the third aspect of the present invention, between after the process for forming the covering film and before the process for exposing an upper part of the first resist pattern, there may be added a process for forming a second resist pattern on the covering film using an organic resist and a process for etching the covering film using the second resist pattern as a mask. This pattern forming method corresponds to a double exposure process and is suitable for forming a fine pattern.

### Effects of the Invention

The coating composition according to the first aspect of the present invention is excellent in the applicability to a substrate on which a resist pattern is formed and in the covering property to the resist pattern. A solvent contained in the coating composition according to the first aspect of the present invention contains, as a main component, a predetermined organic solvent, so that there is hardly observed mixing of the coating composition with a resist pattern. The coating composition according to the first aspect of the present invention is applied to and covers a resist pattern and is baked at a relatively low temperature (80° C. to 150° C.) to enter into a state having no fluidity, that is, a state of being fixed in a certain shape, so that the coating composition can easily be made into a film. The thus obtained covering film exhibits resistance to a resist solvent such as propylene glycol monomethyl ether acetate and propylene glycol monomethyl ether. Further, the coating composition according to the first aspect of the present invention needs no crosslinking agent and an organopolysiloxane contained in the coating composition is not necessary to be limited to that having an epoxy group.

The coating composition according to the first aspect of the present invention is produced by integrating an organopolysiloxane, a solvent containing, as a main component, a predetermined organic solvent, a quaternary ammonium salt or a quaternary phosphonium salt, and components (such as organic acids and surfactants) further added if necessary in the composition to be able to obtain characteristics suitable for being applied to the third aspect of the present invention.

The coating composition according to the second aspect of the present invention is excellent in the applicability to a substrate on which a resist pattern is formed and in the covering property to the resist pattern. A solvent contained in the coating composition according to the second aspect of the present invention contains, as a main component, a predetermined organic solvent, so that there is hardly observed mixing of the coating composition with a resist pattern. When the coating composition according to the second aspect of the present invention contains a crosslinking agent, the coating composition is applied to and covers a resist pattern and is baked at a relatively low temperature (80° C. to 150° C.) to enter into a state having no fluidity, that is, a state of being fixed in a certain shape, so that the coating composition can easily be made into a film. The thus obtained covering film enhances resistance to a resist solvent such as propylene glycol monomethyl ether acetate and propylene glycol monomethyl ether. When instead of the crosslinking agent, a quaternary ammonium salt, a quaternary phosphonium salt, or a sulfonic acid compound is used, the coating composition exhibits the same effect as in the case of containing the crosslinking agent, with proviso that there should be paid attention for such a probability that the composition containing a compound such as a quaternary ammonium salt, a quaternary phosphonium salt, and sulfonic acid in an excessive amount may impair the preservation stability thereof. Further, the coating composition according to the second aspect of the present invention contains a polysilane having no oxygen atom in the backbone thereof, so that the coating composition can enhance its silicon content in comparison with the case of containing a polysiloxane. As a result thereof, it can be expected that the coating composition has high dry etching resistance to an oxygen gas.

The coating composition according to the second aspect of the present invention is produced by integrating a polysilane having, at a terminal thereof, a silanol group or a silanol group together with a hydrogen atom, a solvent containing, as a main component, a predetermined organic solvent, at least one type of additive selected from a group consisting of a crosslinking agent, a quaternary ammonium salt, a quaternary phosphonium salt, and a sulfonic acid compound, and components (such as organic acids and surfactants) further added if necessary in the composition to be able to obtain characteristics suitable for being applied to the third aspect of the present invention.

### BRIEF DESCRIPTION OF THE DRAWINGS

FIGS. 1A, 1B, 1C, and 1D are images produced by photographing a cross section of each of step substrates of isolated line, L/S=1/3, L/S=1/2, and L/S=1/1 used in Example 10 from obliquely above under an SEM, and FIGS. 1a, 1b, 1c, and 1d are images produced by photographing a cross section of each of the samples in which a covering film was formed on the corresponding step substrates from obliquely above under an SEM.

FIG. 2A is a view schematically showing a cross section of the sample in which a resist pattern was formed in Example 11, and FIG. 2B is an image produced by photographing a cross section of the sample from obliquely above under an SEM.

FIG. 3A is a view schematically showing a cross section of the sample in which a covering film was formed in Example 11, and FIG. 3B is an image produced by photographing a cross section of the sample from obliquely above under an SEM.

FIG. 4A is a view schematically showing a cross section of the sample in which a covering film was dry-etched to expose an upper part of a resist pattern in Example 11, and FIG. 4B is an image produced by photographing a cross section of the sample from obliquely above under an SEM.

FIG. 5A is a view schematically showing a cross section of the sample in which a resist pattern and a part of a resist underlayer film were removed by dry-etching in Example 11, and FIG. 5B is an image produced by photographing a cross section of the sample from obliquely above under an SEM.

FIG. 6A is a view schematically showing a cross section of the sample in which a covering film was formed in Example 12, FIG. 6B is an image produced by photographing a cross section of the sample from obliquely above under an SEM, and FIG. 6C is an image produced by photographing the sample from directly above the covering film under an SEM.

FIG. 7A is a view schematically showing a cross section of the sample in which a covering film was dry-etched to expose an upper part of a resist pattern in Example 12, FIG. 7B is an image produced by photographing a cross section of the sample from obliquely above under an SEM, and FIG. 7C is an image produced by photographing the sample from directly above the surface of the formed resist pattern under an SEM.

FIG. 8A is a view schematically showing a cross section of the sample in which a resist pattern was removed by dry-etching in Example 12, FIG. 8B is an image produced by photographing a cross section of the sample from obliquely above under an SEM, and FIG. 8C is an image produced by photographing the sample from directly above the surface of the formed resist pattern under an SEM.

### BEST MODES FOR CARRYING OUT THE INVENTION

The organopolysiloxane contained in the coating composition according to the first aspect of the present invention is a product obtained by subjecting one type or two or more types of compounds of, for example, Formula (2):

XₘSi(OR²)₄₋ₘ (2)

[where X is a methyl group, an ethyl group, a C₂₋₃ alkenyl group, or a phenyl group; R² is a methyl group or an ethyl group; and m is 0 or 1]

to hydrolysis and a condensation reaction. In Formula (2), when m is 0, the compound of Formula (2) is tetramethoxysilane or tetraethoxysilane. It is preferred that as the raw material for obtaining an organopolysiloxane, two or more types of compounds of Formula (2) are used. During the hydrolysis and/or during the condensation reaction, there can be used an acid such as hydrochloric acid, nitric acid, maleic acid, and acetic acid.

The above product, that is, an organopolysiloxane has a silanol group at a terminal thereof. The organopolysiloxane may further have, besides a silanol group, a methoxy group, or an ethoxy group. By analyzing the coating composition according to the present invention using an FT-NIR (Fourier-transform near infrared) spectroscopic apparatus, the existence of a silanol group can be estimated.

The organopolysiloxane is a general term for polymers having a backbone composed of a siloxane bond (a structure in which Si and O are linked alternatively to each other) and having a hydrocarbon group in side chains thereof. A polymer or an oligomer having a unit structure of, for example, Formula (3):

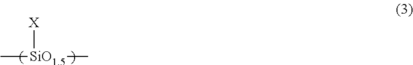

[where X is the same as defined in Formula (2)]

belongs to the organopolysiloxane. The backbone of the organopolysiloxane may be in any one of a cage shape, a ladder shape, a linear shape, and a branched shape. For enhancing the silicon content of the polysiloxane, as X in Formula (3), a methyl group or an ethyl group is preferred.

The polysilane contained in the coating composition according to the second aspect of the present invention has at least one type of unit structure of, for example, Formula (4a) and/or Formula (4b):

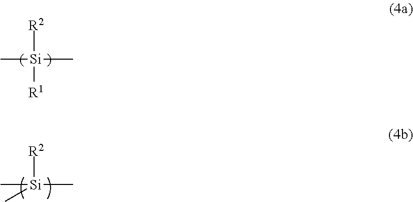

[where each R² is a methyl group, an ethyl group, a C₂-3 alkenyl group, or a phenyl group; and R¹ is a hydrogen atom, a methyl group, or an ethyl group].

The polysilane contained in the coating composition according to the second aspect of the present invention has a silanol group or a silanol group together with a hydrogen atom at a terminal thereof. By analyzing the composition using an FT-NIR (Fourier-transform near infrared) spectroscopic apparatus, the existence of a silanol group can be estimated.

The polysilane is a polymer having a backbone composed of a Si—Si bond. Specific examples of the unit structure of Formula (4a) and specific examples of the unit structure of Formula (4b) include unit structures of Formula (5) to Formula (16):

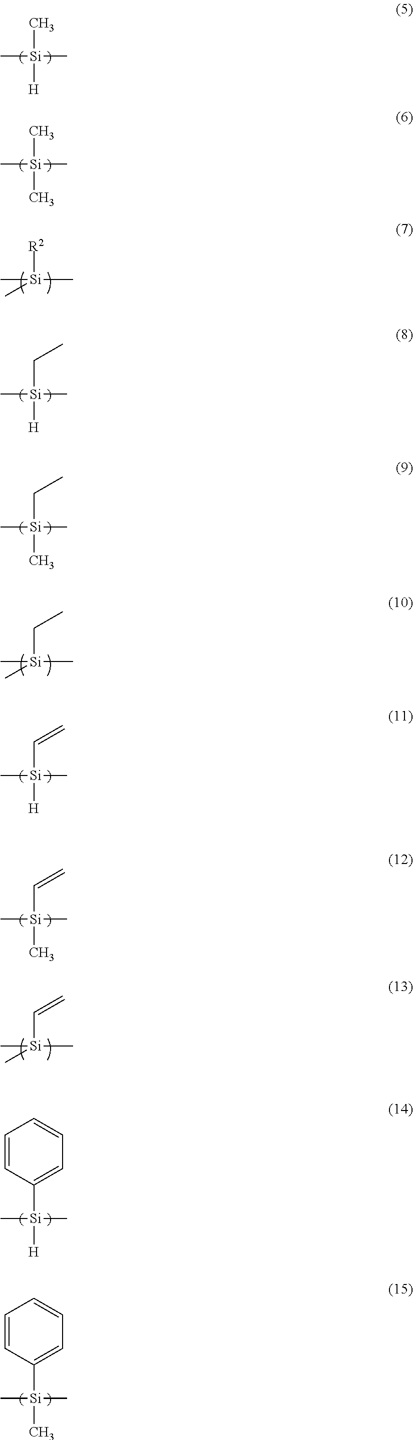

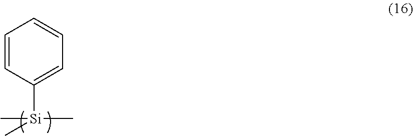

to which the specific examples are not limited.

For enhancing the silicon content of the polysilane, as R² in Formula (4a) or Formula (4b), a methyl group or an ethyl group is preferred, and as R¹ in Formula (4a), a hydrogen atom, a methyl group, or an ethyl group is preferred. The backbone of the polysilane may be in any one of linear shape and branched shape.

The solvent contained in the coating composition according to the first aspect and the second aspect of the present invention and containing an organic solvent of Formula (1a), Formula (1b), or Formula (1c) as a main component contains the organic solvent in an amount of more than 50% by mass, preferably 60% by mass or more and 100% by mass or less. Examples of such an organic solvent include 4-methyl-2-pentanol, 1-butanol, propylene glycol n-propyl ether, propylene glycol n-butyl ether, propylene glycol phenyl ether, dipropylene glycol n-propyl ether, dipropylene glycol n-butyl ether, dipropylene glycol dimethyl ether, tripropylene glycol methyl ether, propylene glycol diacetate, cyclohexanol acetate, and cyclohexanol. Among them, an optimal organic solvent may be selected corresponding to the type of the organic resist used for forming a resist pattern. Examples of the other component of the solvent include dipropylene glycol methyl ether, tripropylene glycol n-butyl ether, dipropylene glycol methyl ether acetate, 1,3-butylene glycol diacetate, methyl acetate, ethyl acetate, isopropyl acetate, n-propyl alcohol, n-propyl acetate, butyl acetate, propylene glycol monomethyl ether, propylene glycol monomethyl ether acetate, ethylene glycol monobutyl ether acetate, diethylene glycol monoethyl ether, diethylene glycol monoethyl ether acetate, diethylene glycol monobutyl ether, diethylene glycol monobutyl ether acetate, 3-methoxybutanol, 3-methoxybutyl acetate, 1,3-butylene glycol, triacetin, ethylene glycol monomethyl ether acetate, ethylene glycol monoethyl ether, ethylene glycol monoethyl ether acetate, ethyl lactate, and cyclohexanone. These solvents may be used as a sub component of the solvent.

The solvent is necessary to hardly cause mixing with the resist pattern and moreover, to have advantageous applicability to a substrate on which a resist pattern is formed. An organic solvent having a boiling point under 1 atm (101.3 kPa) of 100° C. or less is easily volatilized during the application of the composition and water has large surface tension and is difficult to be applied uniformly. Therefore, it cannot be mentioned that the composition using these solvents as a main component of the solvent has advantageous applicability to a substrate. However, it is allowable that the composition contains at least one of the organic solvent having a boiling point of 100° C. or less and water as a sub component of the solvent.

Examples of the quaternary ammonium salt contained in the coating composition according to the first aspect of the present invention include benzyltriethylammonium chloride, benzyltrimethylammonium chloride, benzyltributylammonium chloride, tetramethylammonium chloride, tetraethylammonium bromide, tetraethylammonium chloride, tetrapropylammonium bromide, tetrabutylammonium bromide, tributylmethylammonium chloride, trioctylmethylammonium chloride, and phenyltrimethylammonium chloride. Examples of the quaternary phosphonium salt contained in the coating composition according to the first aspect of the present invention include ethyltriphenylphosphonium bromide, ethyltriphenylphosphonium iodide, benzyltriphenylphosphonium chloride, butyltriphenylphosphonium bromide, and tetrabutylphosphonium bromide. The quaternary ammonium salt and the quaternary phosphonium salt can accelerate the condensation between the silanol groups existing at terminals of organopolysiloxanes, so that it is considered that these salts enhance curing property of the coating composition according to the first aspect of the present invention.

When the coating composition according to the second aspect of the present invention contains a quaternary ammonium salt, examples of the quaternary ammonium salt include benzyltriethylammonium chloride, benzyltrimethylammonium chloride, benzyltributylammonium chloride, tetramethylammonium chloride, tetraethylammonium bromide, tetraethylammonium chloride, tetrapropylammonium bromide, tetrabutylammonium bromide, tributylmethylammonium chloride, trioctylmethylammonium chloride, and phenyltrimethylammonium chloride. When the coating composition according to the second aspect of the present invention contains a quaternary phosphonium salt, examples of the quaternary phosphonium salt include ethyltriphenylphosphonium bromide, ethyltriphenylphosphonium iodide, benzyltriphenylphosphonium chloride, butyltriphenylphosphonium bromide, and tetrabutylphosphonium bromide. The quaternary ammonium salt and the quaternary phosphonium salt can accelerate the condensation between the silanol groups existing at terminals of polysilanes, so that it is considered that these salts further enhance curing property of the coating composition according to the second aspect of the present invention. However, it cannot be mentioned as preferable for the coating composition according to the second aspect of the present invention that the quaternary ammonium salt or the quaternary phosphonium salt coexists with the below-described sulfonic acid compound.

When the coating composition according to the second aspect of the present invention contains a crosslinking agent, the crosslinking agent is a nitrogen-containing compound having two to four nitrogen atoms to which a methylol group or an alkoxymethyl group is bonded. Examples of such a crosslinking agent include hexamethoxymethylmelamine, tetramethoxymethylbenzoguanamine, 1,3,4,6-tetrakis (methoxymethyl) glycoluril, 1,3,4,6-tetrakis (butoxymethyl) glycoluril, 1,3,4,6-tetrakis (hydroxymethyl) glycoluril, 1,3-bis(hydroxymethyl)urea, 1,1,3,3-tetrakis (butoxymethyl)urea, and 1,1,3,3-tetrakis (methoxymethyl)urea.

When the coating composition according to the second aspect of the present invention contains a compound (crosslinking catalyst) accelerating a crosslinking reaction, examples of the crosslinking catalyst include sulfonic acid compounds such as p-toluenesulfonic acid, trifluoromethanesulfonic acid, pyridinium-p-toluenesulfonate, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, and pyridinium-1-naphthalenesulfonate.

In the coating composition according to the first aspect and the second aspect of the present invention, an organic acid may further be added. Examples of the organic acid include cis-type dicarboxylic acids such as maleic acid, cis-5-norbornene-endo-2,3-dicarboxylic acid, cis-5-norbornene-exo-2,3-dicarboxylic acid, and cis-1,2-cyclohexanedicarboxylic acid.

In the coating composition according to the first aspect of the present invention, together with or instead of the organic acid, water may be added for, for example, enhancing the preservation stability of the composition.

In the coating composition according to the first aspect and the second aspect of the present invention, a surfactant may further be added. The surfactant can further enhance the applicability of the coating composition to a substrate and examples of the surfactant include nonionic surfactants and fluorinated surfactants.

When a component remaining after subtracting a solvent from the coating composition according to the first aspect and the second aspect of the present invention is regarded as the solid content, the ratio of the solid content is, for example, 1% by mass or more and 30% by mass or less, based on the mass of the composition. The ratio of the quaternary ammonium salt or the quaternary phosphonium salt may be, for example, 0.001% by mass or more and 5% by mass or less, based on the mass of the solid content. The ratio of the crosslinking agent may be, for example, 0.1% by mass or more and 25% by mass or less and the ratio of the crosslinking catalyst may be, for example, 0.01% by mass or more and 5% by mass or less, based on the mass of the solid content. The ratio of the organic acid may be, for example, 0.1% by mass or more and 10% by mass or less, based on the mass of the solid content. The ratio of water may be, for example, 5% by mass or less, or 3% by mass or less, based on the mass of the solid content.

The coating composition according to the present invention is applied to and coats a resist pattern formed on a semiconductor substrate and the resist pattern is formed using an organic resist. The organic resist is any one of a positive resist and a negative resist and examples thereof include chemical amplification type resists photosensitive to a KrF excimer laser, an ArF excimer laser, an EUV (extreme ultraviolet ray), or an electron beam. In the present specification, the “organic resist” is defined as one that does not contain any silicon-containing resist in which a polysiloxane, a polysilane, or the like is used as a base polymer. The resist pattern is formed on a semiconductor substrate preferably through a resist underlayer film produced from one layer or by laminating two or more layers.

Though a silicon wafer is typically used as the semiconductor substrate, there may also be used an SOI (Silicon on Insulator) substrate or a wafer of a compound semiconductor such as gallium arsenide (GaAs), indium phosphide (InP), and gallium phosphide. There may also be used a semiconductor substrate on which an insulating film such as a silicon oxide film, a nitrogen-containing silicon oxide film (SiON film), a carbon-containing silicon oxide film (SiOC film), and a fluorine-containing silicon oxide film (SiOF film) or a low-k film (low-dielectric constant film) is formed.

Hereinafter, the present invention will be further described more specifically referring to Examples which should not be construed as limiting the scope of the present invention.

### EXAMPLES

The average molecular weight of polymers shown in the following Synthesis Examples of the present specification is a measurement result by gel permeation chromatography (hereinafter, abbreviated as GPC). The used apparatus, conditions, and the like are as follows.

GPC apparatus: HLC-8220 GPC (manufactured by Tosoh Corporation)
GPC column: Shodex [registered trade mark] KF803L, KF802, KF801 (manufactured by Showa Denko K.K.)
Column temperature: 40° C.
Solvent: tetrahydrofuran (THF)
Flow rate: 1.0 mL/min
Standard sample: polystyrene (manufactured by Showa Denko K.K.)

### Synthesis Example 1

20.31 g of tetraethoxysilane, 1.49 g of phenyltrimethoxysilane, 8.02 g of methyltriethoxysilane, and 33.34 g of ethanol were charged into a 100 mL flask to be dissolved. The resultant mixed solution was warmed while stirring the solution with a magnetic stirrer to reflux the solution. Next, to the mixed solution, an aqueous solution in which 0.03 g of hydrochloric acid was dissolved in 9.83 g of ion-exchanged water was added. The reaction was effected for 2 hours and the resultant reaction solution was cooled down to room temperature. Then, to the reaction solution, 100 g of 4-methyl-2-pentanol was added, and methanol and ethanol that were reaction by-products, water, and hydrochloric acid were distilled off under reduced pressure to obtain a hydrolysis-condensation product solution. The average molecular weight measured by GPC of the obtained polymer was found to be Mw 5,500, in terms of the standard polystyrene. Here, “Mw” represents a weight average molecular weight in the present specification.

### Synthesis Example 2

76.76 g of tetraethoxysilane, 8.12 g of phenyltrimethoxysilane, and 84.88 g of 4-methyl-2-pentanol were charged into a 300 mL flask to be dissolved. The resultant mixed solution was warmed while stirring the solution with a magnetic stirrer to effect the reaction at 100° C. Next, to the mixed solution, an aqueous solution in which 1.49 g of maleic acid was dissolved in 28.75 g of ion-exchanged water was added. The reaction was effected for 1 hour and the resultant reaction solution was cooled down to room temperature. Then, to the reaction solution, 200 g of propylene glycol monomethyl ether acetate was added and methanol and ethanol which were reaction by-products, and water were distilled off under reduced pressure to obtain a hydrolysis-condensation product solution. The average molecular weight measured by GPC of the obtained polymer was found to be Mw 4,500, in terms of the standard polystyrene.

### Synthesis Example 3

24.99 g of tetraethoxysilane, 9.16 g of methyltriethoxysilane, and 35.86 g of ethanol were charged into a flask to be dissolved. The resultant mixed solution was warmed while stirring the solution with a magnetic stirrer to reflux the solution. Next, to the mixed solution, 12.04 g of a 0.01 M hydrochloric acid aqueous solution was added. Here, “M” represents mol/L in the present specification. The reaction was effected for 2 hours and the resultant reaction solution was cooled down to room temperature. Then, to the reaction solution, 100 g of 4-methyl-2-pentanol was added, and methanol and ethanol that were reaction by-products, water, and hydrochloric acid were distilled off under reduced pressure to obtain a hydrolysis-condensation product solution. The average molecular weight measured by GPC of the obtained polymer was found to be Mw 4,800, in terms of the standard polystyrene.

### Synthesis Example 4

24.96 g of tetraethoxysilane, 6.11 g of methyltriethoxysilane, 2.54 g of vinyltriethoxysilane, and 33.65 g of ethanol were charged into a flask to be dissolved. The resultant mixed solution was warmed while stirring the solution with a magnetic stirrer to reflux the solution. Next, to the mixed solution, 12.04 g of a 0.01 M hydrochloric acid aqueous solution was added. The reaction was effected for 2 hours and the resultant reaction solution was cooled down to room temperature. Then, to the reaction solution, 100 g of 4-methyl-2-pentanol was added, and methanol and ethanol that were reaction by-products, water, and hydrochloric acid were distilled off under reduced pressure to obtain a hydrolysis-condensation product solution. The average molecular weight measured by GPC of the obtained polymer was found to be Mw 4,200, in terms of the standard polystyrene.

### Example 1

To 25 g of the solution obtained in Synthesis Example 1, 0.01 g of benzyltriethylammonium chloride, 0.10 g of maleic acid, and 0.02 g of a surfactant (manufactured by DIC Corporation; trade name: MEGAFAC R-30) were added and thereto, 4-methyl-2-pentanol was further added to prepare a 4.0% by mass solution. Then, the solution was filtered using a polyethylene microfilter having a pore diameter of 0.02 μm to prepare a coating composition (solution).

### Example 2

To 25 g of the solution obtained in Synthesis Example 1, 0.02 g of benzyltriethylammonium chloride, 0.20 g of maleic acid, and 0.02 g of a surfactant (manufactured by DIC Corporation; trade name: MEGAFAC R-30) were added and thereto, 4-methyl-2-pentanol was further added to prepare a 4.0% by mass solution. Then, the solution was filtered using a polyethylene microfilter having a pore diameter of 0.02 μm to prepare a coating composition (solution).

### Example 3

To 25 g of the solution obtained in Synthesis Example 3, 0.01 g of benzyltriethylammonium chloride, 0.10 g of maleic acid, and 0.02 g of a surfactant (manufactured by DIC Corporation; trade name: MEGAFAC R-30) were added and thereto, 4-methyl-2-pentanol was further added to prepare a 4.0% by mass solution. Then, the solution was filtered using a polyethylene microfilter having a pore diameter of 0.02 μm to prepare a coating composition (solution).

### Example 4

To 25 g of the solution obtained in Synthesis Example 4, 0.01 g of benzyltriethylammonium chloride, 0.10 g of maleic acid, and 0.02 g of a surfactant (manufactured by DIC Corporation; trade name: MEGAFAC R-30) were added and thereto, 4-methyl-2-pentanol was further added to prepare a 4.0% by mass solution. Then, the solution was filtered using a polyethylene microfilter having a pore diameter of 0.02 μm to prepare a coating composition (solution).

### Example 5

A polysilane compound of Formula 17:

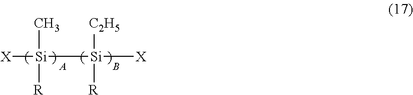

(where each R is independently a hydrogen atom, a methyl group, an ethyl group, an OH group, or a phenyl group; and each X is an OH group, or an OH group and a hydrogen atom)

(manufactured by Osaka Gas Chemicals Co., Ltd.; weight average molecular weight:

5,900, number average molecular weight: 1,800; containing 33 mol % of a unit structure A and 64 mol % of a unit structure B and having, at a terminal thereof, at least a silanol group) was prepared. To 165.0 g of a 4-methyl-2-pentanol solution containing the polysilane compound in a concentration of 20% by mass, 4.16 g of a crosslinking agent (manufactured by Nihon Cytec. Industries, Inc.; trade name: CYMEL [registered trade mark] 303), 0.21 g of a surfactant (manufactured by DIC Corporation; trade name: MEGAFAC R-30), and 0.42 g of p-toluenesulfonic acid were added and thereto, 4-methyl-2-pentanol was further added to prepare a 4.0% by mass solution. Then, the solution was filtered using a polyethylene microfilter having a pore diameter of 0.02 μm to prepare a coating composition (solution).

### Example 6

The polysilane compound used in Example 5 was prepared. To 165.0 g of a 4-methyl-2-pentanol solution containing the polysilane compound in a concentration of 20% by mass, 4.16 g of a crosslinking agent (manufactured by Nihon Cytec Industries, Inc.; trade name: POWDERLINK [registered trade mark] 1174), 0.21 g of a surfactant (manufactured by DIC Corporation; trade name: MEGAFAC R-30), and 0.42 g of p-toluenesulfonic acid were added and thereto, 4-methyl-2-pentanol was further added to prepare a 4.0% by mass solution. Then, the solution was filtered using a polyethylene microfilter having a pore diameter of 0.02 μm to prepare a coating composition (solution).

### Example 7

A polysilane compound of Formula 17 (where each R is independently a hydrogen atom, a methyl group, an ethyl group, an OH group, or a phenyl group; and each X is an OH group, or an OH group and a hydrogen atom) (manufactured by Osaka Gas Chemicals Co., Ltd.; weight average molecular weight: 5,600, number average molecular weight: 1,900; containing 10 mol % of a unit structure A and 90 mol % of a unit structure B and having, at a terminal thereof, at least a silanol group) was prepared. To 165.0 g of a 4-methyl-2-pentanol solution containing the polysilane compound in a concentration of 20% by mass, 4.16 g of a crosslinking agent (manufactured by Nihon Cytec Industries, Inc.; trade name: CYMEL [registered trade mark] 303), 0.21 g of a surfactant (manufactured by DIC Corporation; trade name: MEGAFAC R-30), and 0.42 g of p-toluenesulfonic acid were added to prepare a 4.0% by mass solution. Then, the solution was filtered using a polyethylene microfilter having a pore diameter of 0.02 μM to prepare a coating composition (solution).

### Comparative Example 1

To 25 g of the solution obtained in Synthesis Example 1, 0.10 g of maleic acid and 0.02 g of a surfactant (manufactured by DIC Corporation; trade name: MEGAFAC R-30) were added and thereto, 4-methyl-2-pentanol was further added to prepare a 4.0% by mass solution. Then, the solution was filtered using a polyethylene microfilter having a pore diameter of 0.02 μm to prepare a coating composition (solution). The present Comparative Example is different from Example 1 in terms of using neither quaternary ammonium salt nor quaternary phosphonium salt.

### Comparative Example 2

The polysilane compound used in Example 5 and Example 6 was prepared and thereto, 4-methyl-2-pentanol was added to prepare a 4.0% by mass solution. The solution was filtered using a polyethylene microfilter having a pore diameter of 0.02 μm to prepare a coating composition (solution). The present Comparative Example is different from Example 5 and Example 6 in terms of using no crosslinking agent, no sulfonic acid compound, and no surfactant.

### Example 8

### Dry-Etching Rate

Dry-etching was performed to a covering film formed using each of the coating compositions prepared in Example 1 to Example 7 and Comparative Example 1 and to a photoresist film formed using an organic photoresist (manufactured by Sumitomo Chemical Co., Ltd.; trade name: PAR 855), using CF₄ and O₂ as an etching gas, and the dry-etching rate was measured. The apparatus used for dry-etching was RIE-10NR (manufactured by Samco, Inc.). Then, the ratio (coating film/photoresist film) of a dry-etching rate of the covering film relative to a dry-etching rate of the photoresist film was measured and the result thereof is shown in Table 1.

TABLE 1
Dry-etching rate ratio

| | CF₄ | O₂ |
|---|---|---|
| Example 1 | 1.64 | 0.04 |
| Example 2 | 1.60 | 0.04 |
| Example 3 | 1.71 | 0.04 |
| Example 4 | 1.67 | 0.04 |
| Example 5 | 1.57 | 0.06 |
| Example 6 | 1.63 | 0.04 |
| Example 7 | 1.51 | 0.05 |
| Comparative | 1.58 | 0.04 |
| Example 1 | | |

### Example 9)<

### Solvent Resistance

A silicon wafer was spin-coated with the coating composition prepared in Example 1 and the silicon wafer was baked at 150° C. or 205° C. for 60 seconds to prepare a sample in which a covering film was formed on a silicon wafer. Also with respect to the coating compositions prepared in Example 2, Example 3, Example 4, and Comparative Example 1, samples were prepared in the same manner. To each of the covering films formed in the prepared samples, propylene glycol monomethyl ether acetate (hereinafter, abbreviated as PGMEA) or propylene glycol monomethyl ether (hereinafter, abbreviated as PGME), which is a solvent, was dropped and the covering film was maintained for 60 seconds. Then, the covering film was subjected to spin-drying for 30 seconds and subsequent baking at 100° C. for 30 seconds and the solvent was removed from the sample. There was measured the change in the film thickness of the covering film on the silicon wafer between before dropping the solvent and after removing the dropped solvent. The result of the measurement is shown in Table 2.

TABLE 2

| | PGMEA | PGME |
|---|---|---|
| Example 1 (150° C.) | 0.375 nm | 0.125 nm |
| Example 2 (150° C.) | 0.100 nm | 0.100 nm |
| Example 3 (150° C.) | 0.250 nm | 0.125 nm |
| Example 4 (150° C.) | 0.325 nm | 0.125 nm |
| Comparative Example 1 (150° C.) | 74.05 nm | 79.40 nm |
| Example 1 (205° C.) | 0.400 nm | 0.225 nm |
| Example 2 (205° C.) | 0.300 nm | 0.200 nm |
| Example 3 (205° C.) | 0.375 nm | 0.275 nm |
| Example 4 (205° C.) | 0.400 nm | 0.250 nm |
| Comparative Example 1 (205° C.) | 0.125 nm | 0.300 nm |

A silicon wafer was spin-coated with the coating composition prepared in Example 5 and the silicon wafer was baked at 150° C. for 60 seconds to prepare a sample in which a covering film was formed on a silicon wafer. Also with respect to the coating compositions prepared in Example 6, Example 7, and Comparative Example 2, samples were prepared in the same manner. To each of the covering films formed in the prepared samples, PGMEA, which is a solvent, was dropped and the covering film was maintained for 60 seconds. Then, the covering film was subjected to spin-drying for 30 seconds and subsequent baking at 100° C. for 30 seconds and the solvent was removed from the sample. There was measured the change in the film thickness of the covering film on the silicon wafer between before dropping the solvent and after removing the dropped solvent. The result of the measurement is shown in Table 3.

TABLE 3

| | PGMEA |
|---|---|
| Example 5 (150° C.) | 4.35 nm |
| Example 6 (150° C.) | 3.00 nm |
| Example 7 (150° C.) | 5.75 nm |
| Comparative Example 2 (150° C.) | 98.05 nm |

From the result of Example 9, it is apparent that the covering film formed by using each of the coating compositions prepared in Example 1 to Example 4 and by baking the coating composition at a relatively low temperature (150° C.) has resistance, to at least PGMEA and PGME, larger than that of a covering film formed by using the coating composition prepared in Comparative Example 1 and by baking the coating composition at the same temperature. It is also apparent that the covering film formed by using each of the coating compositions prepared in Example 5 to Example 7 and by baking the coating composition at a relatively low temperature (150° C.) has resistance, to at least PGMEA, larger than that of a covering film formed by using the coating composition prepared in Comparative Example 2 and by baking the coating composition at the same temperature.

### Example 10

### Step Covering Property and Planarity

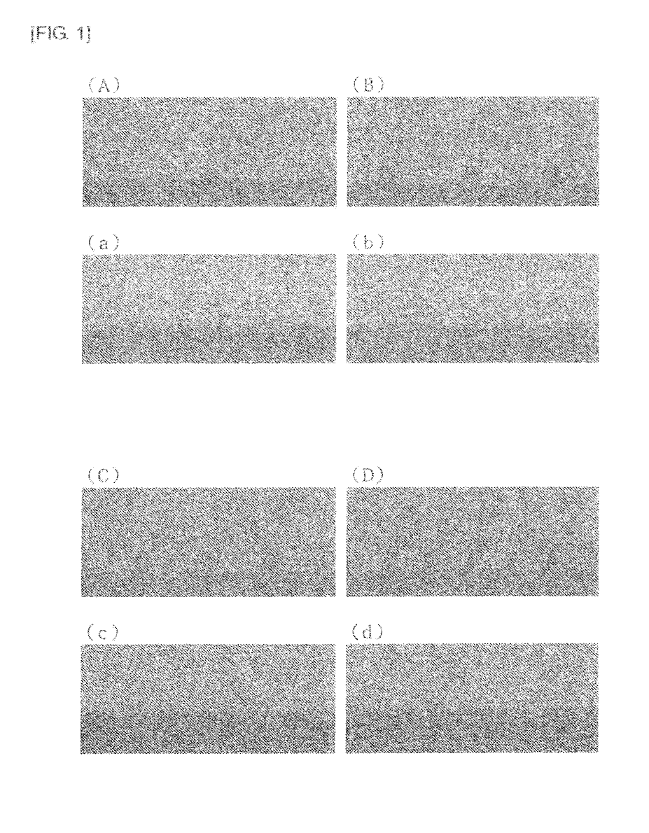

For obtaining an advantageous contact hole using the coating composition according to the present invention, the covering film formed from the coating composition is necessary to have high step covering property and high planarity. Then, using a step substrate in which a step is formed on a silicon substrate, a coating test of the coating composition according to the present invention was performed. The used step substrate was obtained from Advantec Co., Ltd.; and the height of the step was 80 nm, the thickness of the covering film was 110 nm, and the baking temperature and the baking time were 110° C. and 60 seconds, respectively. A total of four types of step substrates including a step substrate having only an isolated line and three types of step substrates having different L/Ss (line and space) were used and each of the step substrates was spin-coated with the coating composition prepared in Example 5, followed by baking the coating composition under the above conditions to form a covering film. Images produced by photographing using a scanning electron microscope (hereinafter, abbreviated as SEM) a cross section of the step substrate before forming the covering film under a scanning electron microscope (hereinafter, abbreviated as SEM) are shown in FIGS. 1A, 1B, 1C, and 1D. Images produced by photographing a cross section of the sample in which the covering film was formed under an SEM are shown in FIGS. 1a, 1b, 1c, and 1d. In each sample, steps of the step substrate were satisfactorily covered.

### Example 11

### Application to “Reversal Patterning”

On a silicon wafer 101, a resist underlayer film 102 was formed using a composition containing a copolymer (having a weight average molecular weight of 30,000 and containing a unit structure (18a), a unit structure (18b), and a unit structure (18c) in a ratio of 34% by mass, 33% by mass, and 33% by mass, respectively) having three types of unit structures of Formulae (18a), (18b), and (18c):

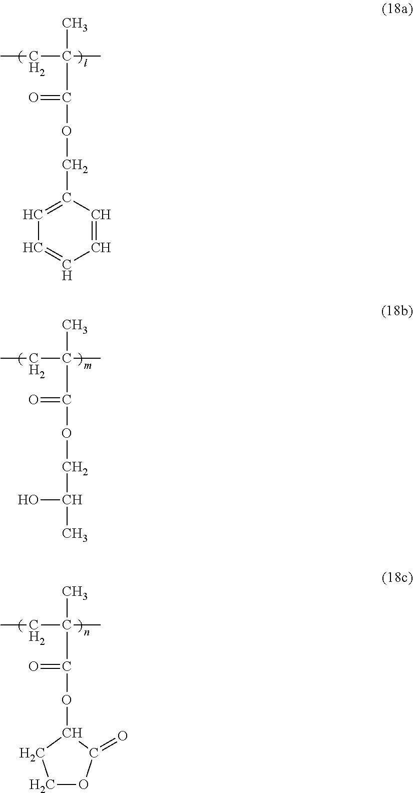

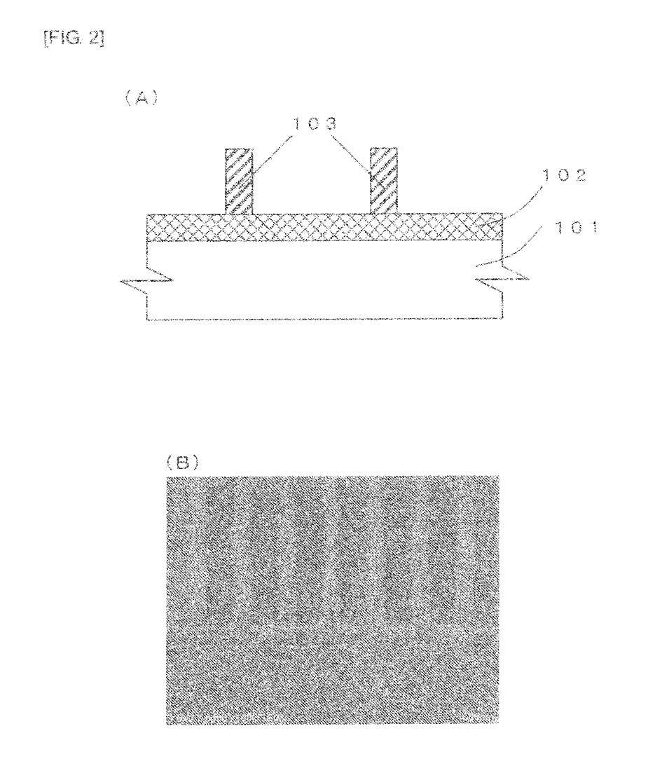

a crosslinking agent (manufactured by Nihon Cytec Industries, Inc.; trade name: POWDERLINK [registered trade mark] 1174), and pyridinium-p-toluenesulfonate, and on the resist underlayer film 102, a resist pattern 103 was formed using an organic photoresist (manufactured by Sumitomo Chemical Co., Ltd.; trade name: PAR 855) as shown in FIG. 2A. The target CD (Critical Dimension) was 80 nm, L/S (line and space)=80/100.

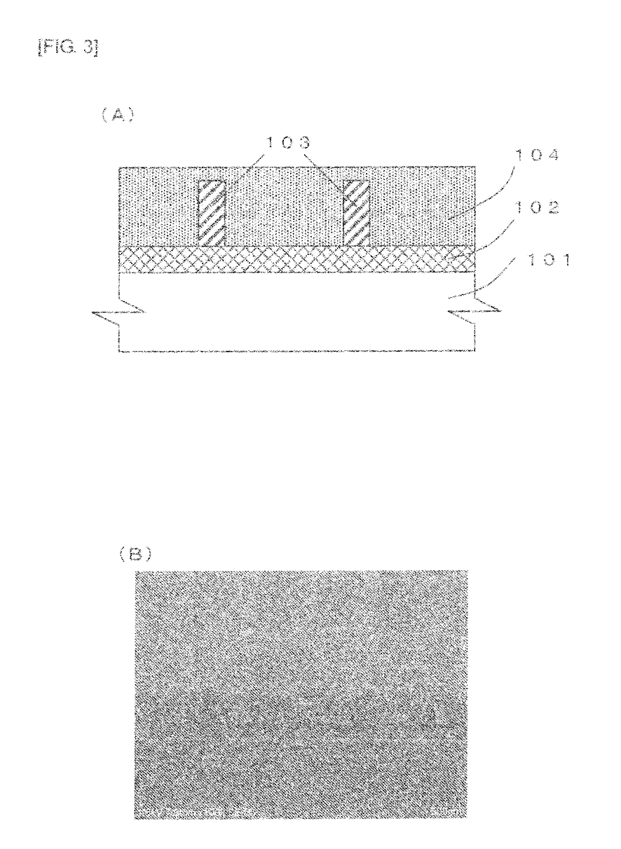

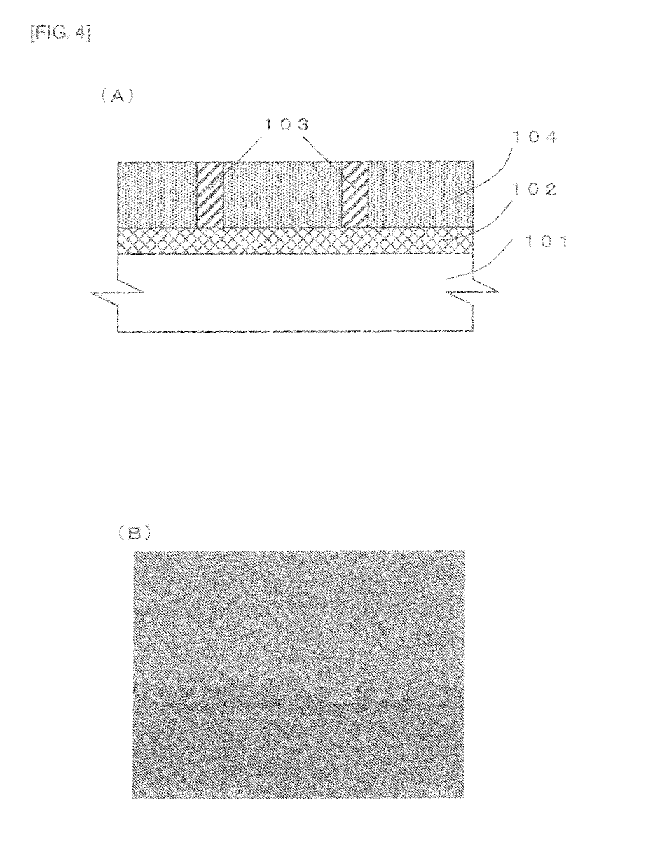

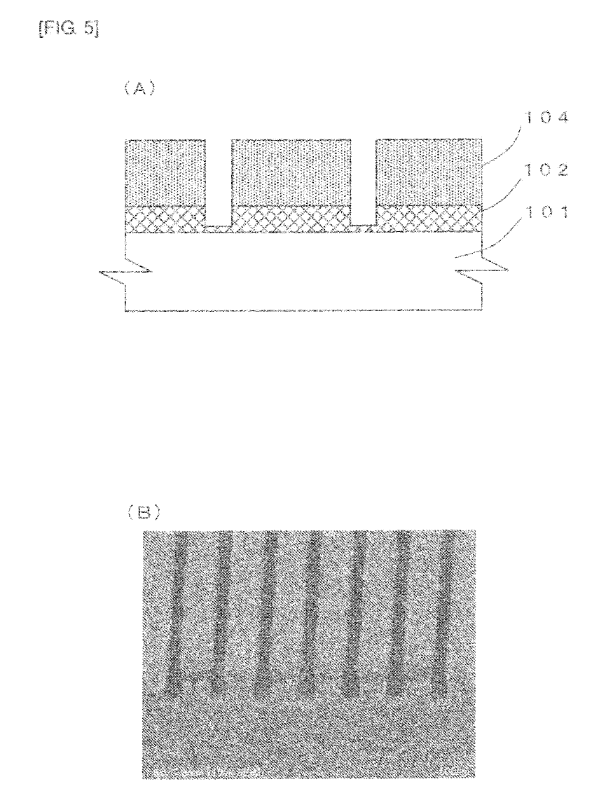

Next, the coating composition prepared in Example 1 was spin-coated so as to cover the resist pattern 103 and was baked at 110° C. for 60 seconds to form a covering film 104 as shown in FIG. 3A. Then, dry-etching using CF₄ as an etching gas was performed to expose an upper part of the resist pattern 103 as shown in FIG. 4A. FIG. 4A is depicted as the top face of the resist pattern 103 and the top face of the covering film 104 are in one plane. However, depending on conditions of dry-etching, the upper part of the resist pattern 103 may be etched, and thus the top face of the resist pattern may slightly become concave in shape from the top face of the covering film 104. Finally, dry-etching using O₂ as an etching gas was performed to remove the resist pattern 103 as shown in FIG. 5A. FIG. 5A shows the case where together with the resist pattern 103, at least a part of the resist underlayer film 102 is etched.

FIG. 2B shows an image produced by photographing a cross section of the sample corresponding to FIG. 2A under an SEM. FIG. 3B shows an image produced by photographing a cross section of the sample corresponding to FIG. 3A under an SEM. FIG. 4B shows an image produced by photographing a cross section of the sample corresponding to FIG. 4A under an SEM. FIG. 5B shows an image produced by photographing a cross section of the sample corresponding to FIG. 5A under an SEM. FIG. 5B shows that a pattern in a shape produced by inverting the shape of the resist pattern is formed.

### Example 12

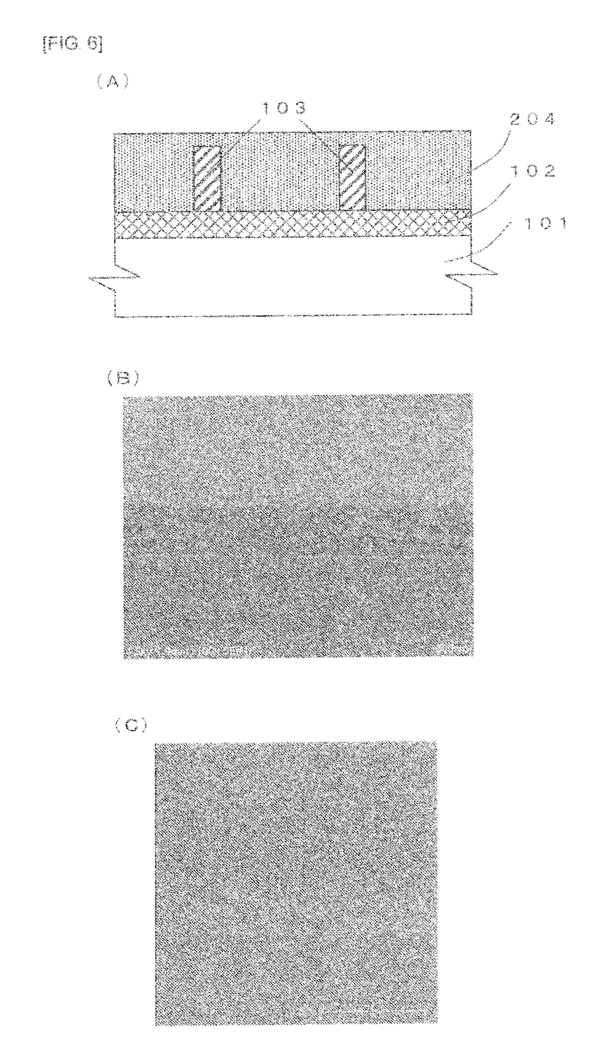

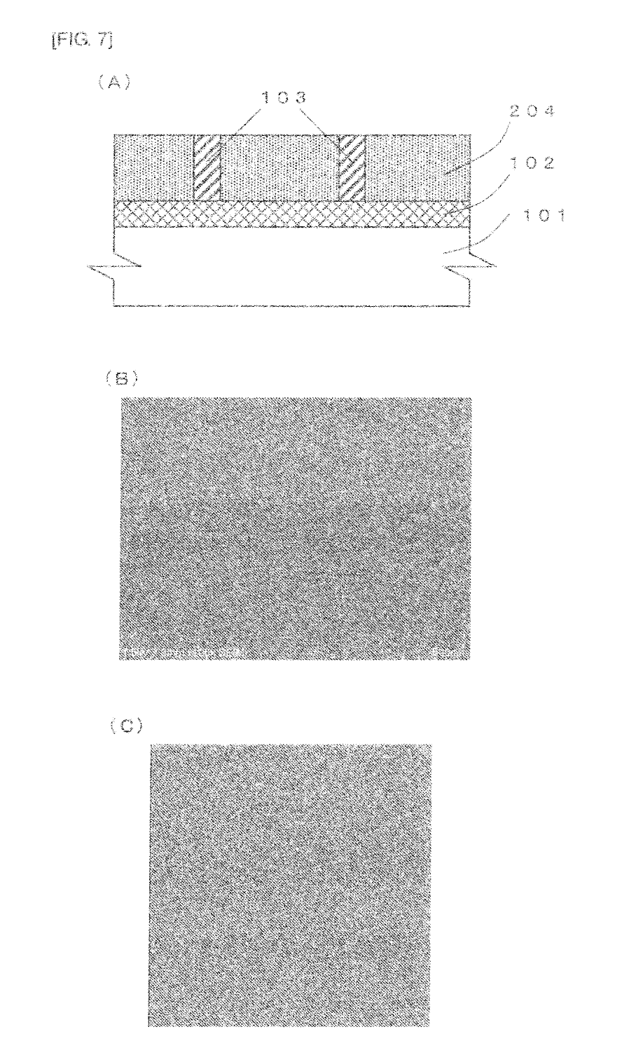

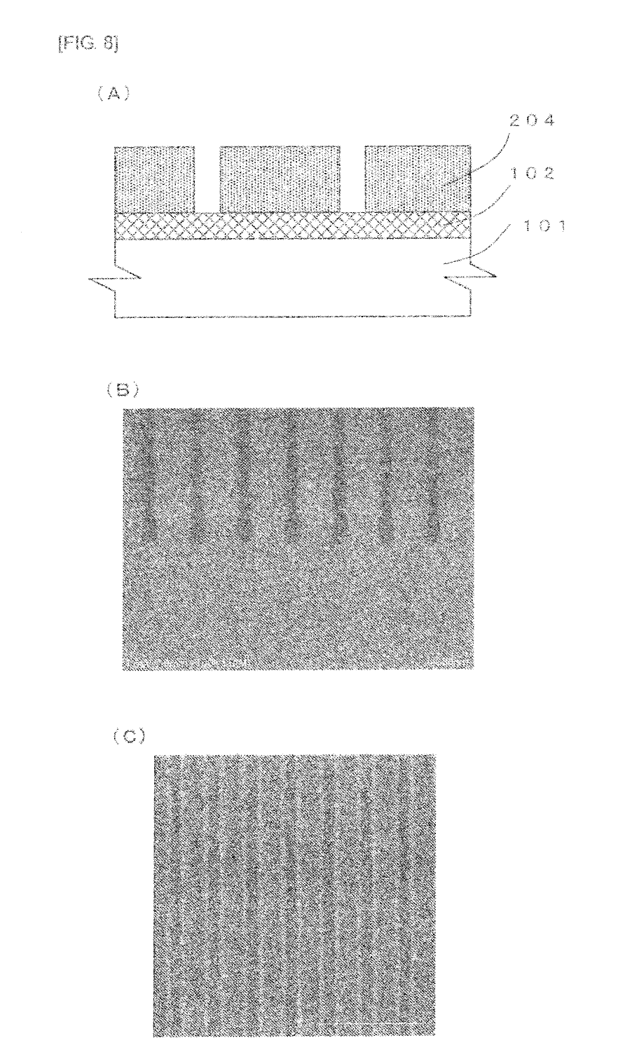

Next, the coating composition prepared in Example 5 was spin-coated so as to cover the resist pattern 103 and was baked at 110° C. for 60 seconds to form a covering film 204 as shown in FIG. 6A. Then, dry-etching using CF₄ as an etching gas was performed to expose an upper part of the resist pattern 103 as shown in FIG. 7A. Finally, dry-etching using O₂ as an etching gas was performed to remove the resist pattern 103 as shown in FIG. 8A.

FIG. 6B and FIG. 6C show images produced by photographing a cross section and a top face, respectively, of the sample corresponding to FIG. 6A under an SEM. FIG. 7B and FIG. 7C show images produced by photographing a cross section and a top face, respectively, of the sample corresponding to FIG. 7A under an SEM. FIG. 8B and FIG. 8C show images produced by photographing a cross section and a top face, respectively, of the sample corresponding to FIG. 8A under an SEM. FIG. 8B and FIG. 8C show that a pattern in a shape produced by inverting the shape of the resist pattern is formed.

### DESCRIPTION OF THE REFERENCE NUMERALS

101 Silicon wafer
102 Resist underlayer film
103 Resist pattern
104 Covering film formed from the coating composition prepared in Example 1
204 Covering film formed from the coating composition prepared in Example 5

1. A coating composition for lithography for forming a film covering a resist pattern, comprising:
an organopolysiloxane;
a solvent containing, as a main component, an organic solvent of Formula (1a), Formula (1b), or Formula (1c):
A¹(OA³)ₙOA² (1a)
A⁴OH (1b)
A⁵O(CO)CH₃ (1c)
[where A¹ is a hydrogen atom, a linear, branched, or cyclic C₁₋₆ hydrocarbon group, or an acetyl group; A² is a hydrogen atom, a methyl group, or an acetyl group; A³ is a linear or branched divalent C₂₋₄ hydrocarbon group; A⁴ is a linear, branched, or cyclic C₃₋₆ hydrocarbon group; A⁵ is a linear, branched, or cyclic C₁₋₆ hydrocarbon group; and n is 1 or 2]; and
a quaternary ammonium salt or a quaternary phosphonium salt.

2. The coating composition for lithography according to claim 1, wherein the organopolysiloxane has a backbone in a cage shape, a ladder shape, a linear shape, or a branched shape.

3. The coating composition for lithography according to claim 1, wherein the organopolysiloxane is a product obtained by subjecting one type or two or more types of compounds of Formula (2):
XₘSi(OR²)₄₋ₘ (2)
[where X is a methyl group, an ethyl group, a C₂₋₃ alkenyl group, or a phenyl group; R² is a methyl group or an ethyl group; and m is 0 or 1]
to hydrolysis and a condensation reaction.

4. A coating composition for lithography for being applied to and covering a resist pattern, comprising:
a polysilane;
a solvent containing, as a main component, an organic solvent of Formula (1a), Formula (1b), or Formula (1c):
A¹(OA³)ₙOA² (1a)
A⁴OH (1b)
A⁵O(CO)CH₃ (1c)
[where A¹ is a hydrogen atom, a linear, branched, or cyclic C₁₋₆ hydrocarbon group, or an acetyl group; A² is a hydrogen atom, a methyl group, or an acetyl group; A³ is a linear or branched divalent C₂₋₄ hydrocarbon group; A⁴ is a linear, branched, or cyclic C₃₋₆ hydrocarbon group; A⁵ is a linear, branched, or cyclic C₁₋₆ hydrocarbon group; and n is 1 or 2]; and
at least one type selected from a group consisting of a crosslinking agent, a quaternary ammonium salt, a quaternary phosphonium salt, and a sulfonic acid compound, wherein the polysilane has, at a terminal thereof, a silanol group or a silanol group together with a hydrogen atom.

5. The coating composition for lithography according to claim 4, wherein the polysilane has a backbone in a linear shape or a branched shape.

6. The coating composition for lithography according to claim 4, wherein the polysilane has at least one type of unit structure of Formula (4a) and/or Formula (4b): 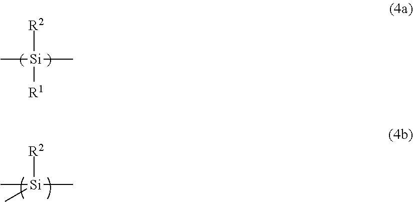
[where each R² is a methyl group, an ethyl group, a C₂₋₃ alkenyl group, or a phenyl group; and R¹ is a hydrogen atom, a methyl group, or an ethyl group].

7. The coating composition for lithography according to claim 4, wherein the crosslinking agent is a nitrogen-containing compound having two to four nitrogen atoms to which a methylol group or an alkoxymethyl group is bonded.

8. The coating composition for lithography according to claim 1, wherein the organic solvent is 4-methyl-2-pentanol, propylene glycol n-propyl ether, propylene glycol n-butyl ether, propylene glycol phenyl ether, dipropylene glycol n-propyl ether, dipropylene glycol n-butyl ether, dipropylene glycol dimethyl ether, tripropylene glycol methyl ether, propylene glycol diacetate, cyclohexanol acetate, or cyclohexanol.

9. The coating composition for lithography according to claim 1, further comprising an organic acid.

10. The coating composition for lithography according to claim 1, further comprising a surfactant.

11. A pattern forming method comprising:
forming a first resist pattern on a semiconductor substrate on which a layer to be processed is formed using an organic resist;
applying the coating composition as claimed in claim 1 so as to cover the first resist pattern;
forming a covering film by baking the coating composition;
exposing an upper part of the first resist pattern by etching the covering film; and
removing a part or the whole of the first resist pattern to form a pattern of the covering film.

12. The pattern forming method according to claim 11, further comprising:
forming a second resist pattern on the covering film using an organic resist; and
etching the covering film using the second resist pattern as a mask; after the forming of a covering film and before the exposing of an upper part of the first resist pattern.

13. The coating composition for lithography according to claim 4, wherein the organic solvent is 4-methyl-2-pentanol, propylene glycol n-propyl ether, propylene glycol n-butyl ether, propylene glycol phenyl ether, dipropylene glycol n-propyl ether, dipropylene glycol n-butyl ether, dipropylene glycol dimethyl ether, tripropylene glycol methyl ether, propylene glycol diacetate, cyclohexanol acetate, or cyclohexanol.

14. The coating composition for lithography according to claim 4, further comprising an organic acid.

15. The coating composition for lithography according to claim 4, further comprising a surfactant.

16. A pattern forming method comprising:
forming a first resist pattern on a semiconductor substrate on which a layer to be processed is formed using an organic resist;
applying the coating composition as claimed in claim 4 so as to cover the first resist pattern;
forming a covering film by baking the coating composition;
exposing an upper part of the first resist pattern by etching the covering film; and
removing a part or the whole of the first resist pattern to form a pattern of the covering film.

17. The pattern forming method according to claim 16, further comprising:
forming a second resist pattern on the covering film using an organic resist; and
etching the covering film using the second resist pattern as a mask; after the forming of a covering film and before the exposing of an upper part of the first resist pattern.
